(19) United States
(12) Patent Application Publication
(10) Pub. No.: US 2025/0151582 A1
(43) Pub. Date: May 8, 2025

(54) DISPLAY DEVICE

(71) Applicant: LG Display Co., Ltd., Seoul (KR)

(72) Inventors: Sein SON, Seoul (KR); Seungmin BAIK, Gimpo-si (KR); Kisuk KANG, Seoul (KR)

(21) Appl. No.: 18/924,749

(22) Filed: Oct. 23, 2024

(30) Foreign Application Priority Data
Nov. 6, 2023 (KR) 10-2023-0151771

(51) Int. Cl. H10K 59/80; H10K 59/131

(52) U.S. Cl. CPC H10K 59/873; H10K 59/131; H10K 59/8792

(57) ABSTRACT

The present specification relates to a display device in which reliability can be secured and a narrow bezel can be implemented by removing a structure of a dam, such as an engraved dam or an embossed dam, from a bezel area of the display device. To achieve this, in the display device according to the present specification, by forming a surrounding through hole in the form of surrounding an active area to pass through a display panel in a bezel area of the display panel and when a particle cover layer is formed in a manufacturing process, radiating ultraviolet light through the surrounding through hole of the bezel area to cure the particle cover layer, it is possible to remove a structure of a dam, thereby preventing the occurrence of defects in the bezel area.

### CROSS REFERENCE TO RELATED APPLICATION

The present application claims priority to Korean Patent Application No. 10-2023-0151771, filed Nov. 6, 2023, the entire contents of which is incorporated herein for all purposes by this reference.

### BACKGROUND

### Technical Field

The present specification relates to a display device, and more specifically, to a display device in which the quality is improved by preventing the occurrence of traces of a seam visible from a bezel area of a display panel.

### Description of the Related Art

Display devices include an active area in which images are displayed and a non-active area formed along an outer edge portion of the active area. In addition to the display panel for displaying the images, the display device requires various additional components such as a driving integrated circuit or a circuit board.

Additional components may be located in the non-active area, or various connection components, such as a flexible printed circuit board, for connecting the additional components may be located therein.

In the display device, the non-active area includes a bezel area, and the bezel area may be bent at 180 degrees and permanently maintain a folded shape.

### BRIEF SUMMARY

Conventional display devices are manufactured in the form of applying a trench structure to a bezel area to form an engraved dam DAM and having the engraved dam filled with a particle cover layer (PCL).

Therefore, the bezel area has a tapered area at 90° due to the trench structure, and such a tapered area causes reliability defects that are visible by traces of a seam.

Therefore, there is a problem in that since the reliability of the display device cannot be secured due to defects in the bezel area, there is the limitation in implementing a stable narrow bezel.

To address the various technical problems in the related art including the above identified problem, the inventors of the present specification provided various embodiments of a display device. One example includes a display device in which reliability can be secured and a narrow bezel can be implemented by removing a structure of a dam, such as an engraved dam or an embossed dam, from a bezel area of the display device and preventing the occurrence of defects in the bezel area.

Embodiments of the present specification are directed to providing a display device in which a surrounding through hole passes through a display panel in the form of surrounding an active area in a bezel area of the display panel and when a particle cover layer PCL is formed in a manufacturing process, radiates ultraviolet light through the surrounding through hole of the bezel area to cure the particle cover layer PCL.

The technical benefits of the present specification are not limited to the above-described benefits, and other benefits and advantages of the present specification which are not mentioned can be understood by the following description and more clearly understood by embodiments of the present specification. In addition, it will be able to be easily seen that the benefits and advantages of the present specification can be achieved by devices and combinations thereof that are described in the claims.

There may be provided a display device according to one embodiment of the present specification. In the display device, a surrounding through hole passing through a display panel in the form of surrounding the periphery of an active area may be disposed in a bezel area (BZA) disposed near an active area (AA) in which one or more pixels are disposed.

The surrounding through hole (SRH) may be filled with transparent ink, a glass material, or a transparent material.

The surrounding through hole (SRH) may be disposed between one or more anode electrode electrodes disposed in the bezel area and one or more pixels disposed at the periphery of the active area.

### BRIEF DESCRIPTION OF THE SEVERAL VIEWS OF THE DRAWINGS

FIG. 1 is a view showing a front surface of a display device according to an embodiment of the present specification.

FIG. 2 is an enlarged view of area A in FIG. 1 in the display device according to the embodiment of the present specification.

FIG. 3 is a cross-sectional view of the display device according to the embodiment of the present specification.

FIG. 4 is a cross-sectional view of an active area in the display device according to the embodiment of the present specification.

FIG. 5 is a view showing an example in which a particle cover layer is cured through a surrounding through hole according to the embodiment of the present specification.

FIG. 6 is a block diagram schematically showing a systematic configuration of the display device according to the embodiment of the present specification.

FIG. 7 is a view showing an active area, a bending area, and a pad area in a display panel according to the embodiment of the present specification.

FIG. 8 is a view showing a structure of area B in FIG. 7 in the display device according to the embodiment of the present specification.

FIG. 9 is a cross-sectional view along line C-C′ in FIG. 8 in the display device according to the embodiment of the present specification.

FIGS. 10A and 10B are views showing an example in which the particle cover layer is cured by light radiated through a surrounding through hole of a wafer substrate in a process of manufacturing the display device.

FIGS. 11A and 11B are views showing an example in which the particle cover layer is cured by light radiated through a surrounding through hole of a black matrix in the process of manufacturing the display device.

FIGS. 12A to 12D are views showing a process of curing the particle cover layer by radiating light through the surrounding through hole according to the embodiment of the present specification.

### DETAILED DESCRIPTION

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary embodiments according to the present disclosure will be described in detail with reference to the accompanying drawings. In the drawings, the same reference numerals are used to denote the same or similar components.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when a first component is described as being “connected,” “coupled,” or “joined” to a second component, the components may be directly connected or joined, but it should be understood that a third component may be “interposed” between the components, or the components may be “connected,” “coupled,” or “joined” through the third component.

Unless otherwise defined, all terms (including technical and scientific terms) used in the specification may be used as meaning commonly understood by those skilled in the art to which the present disclosure pertains. In addition, terms defined in commonly used dictionaries are not construed ideally or excessively unless clearly and specially defined.

Hereinafter, according to embodiments of the present specification, a display device in which reliability can be secured and a narrow bezel can be implemented by removing a structure of a dam, such as an engraved dam or an embossed dam, from a bezel area of the display device and preventing the occurrence of defects in the bezel area will be described.

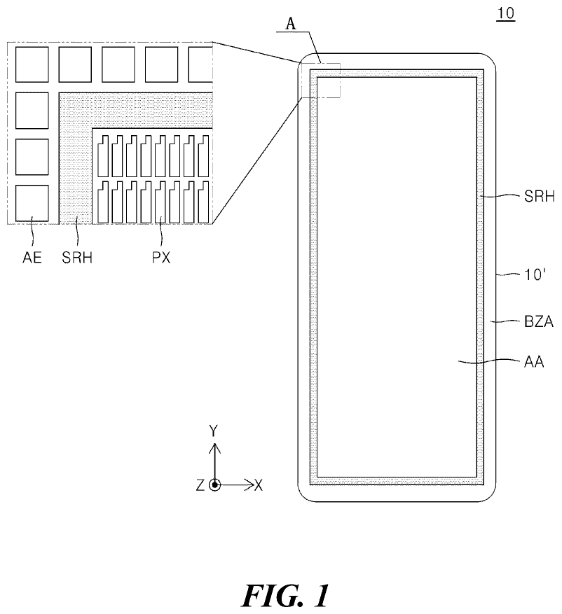

FIG. 1 is a view showing a front surface of a display device according to an embodiment of the present specification.

FIG. 1 schematically shows a front surface of a display device 10 in which an active area AA is located. Front surface and upward directions defined herein indicate a Z-axis direction, and back surface and downward directions indicate a −Z-axis direction.

Referring to FIG. 1, the display device 10 according to the specification of the present disclosure may include a display panel 10′ disposed on the front surface thereof.

The display panel 10′ may include an active area AA in which one or more pixels PX are disposed, and a bezel area BZA disposed adjacent to or near the active area. The bezel area BZA may be disposed along an outermost edge of the display device 10 in the form of surrounding the active area AA.

One pixel PX of the one or more pixels may include an anode electrode, a light emitting layer, and a cathode electrode. The one pixel PX may be referred to as a light emitting element PX.

A surrounding through hole SRH extending into the display panel 10′ (or in some embodiments, passing through the display panel 10′) in the form of surrounding the active area AA may be disposed in the bezel area BZA.

The surrounding through hole SRH may be disposed in the bezel area BZA between one or more anode electrodes AE disposed in the bezel area BZA and one or more pixels PX disposed at the periphery of the active area AA.

The surrounding through hole SRH may be filled with a material that transmits light, such as transparent ink, a glass (GLS) material, a transparent organic material, etc. The transparent organic material may include polyimide. Accordingly, in the display device 10, the surrounding through hole SRH has a material inside the surrounding through hole SRH that transmits light, such as transparent ink, or a glass (GLS) material, or a transparent organic material, or the like.

Although not shown in the drawings, a cover member may be disposed on the display panel 10′. The cover member may be made of, for example, cover glass (CG). The cover member may be disposed to cover a front surface of the display panel 10′ to protect the display panel 10′ from an external impact. An edge portion of the cover member may have a rounded shape formed to be curved toward a back surface of the display panel 10′.

Since the cover member includes the active area AA in which the images are displayed, the cover member may be made of a transparent material, such as cover glass, to display the images. For example, the cover member may be made of a transparent plastic, glass, or reinforced glass material.

Although the display panel 10′ is not shown in the drawing, a back frame may be disposed at a back side thereof. The back frame may be disposed on the back surface of the display panel 10′ and may be in contact with the cover member to accommodate the display panel 10′ and support the cover member.

The back frame may serve as a housing forming an outer rear surface of the display device 10 and may be made of a metal material such as aluminum (Al) or a polymer epoxy-based resin material. The embodiments of the present specification are not limited thereto.

In this case, the back frame may serve as a case forming the outermost portion of the display device 10, but is not limited thereto. For example, the back frame may serve as a middle frame portion that serves as a housing for protecting the rear surface of the display panel 10′.

As shown in FIG. 1, the surrounding through hole SRH surrounds the active area AA of the display panel 10′ when seen from a plan view.

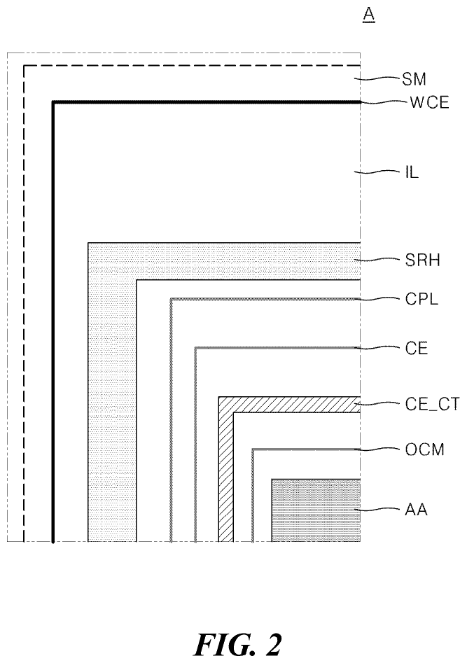

FIG. 2 is an enlarged view of area A in FIG. 1 (a corner of the display panel at the periphery of the display panel) in the display device according to the embodiment of the present specification.

Referring to FIG. 2, in the display device 10 according to the embodiment of the present specification, a light emitting layer mask OCM, a cathode electrode contact CE_CT, a cathode electrode CE, a cathode capping layer CPL may be disposed between the surrounding through hole SRH and the active area AA.

The light emitting layer mask OCM is a mask used to form a light emitting layer EL.

The cathode electrode contact CE_CT is a contact electrode or contact wire for grounding the cathode electrode CE and the anode electrode AE.

The cathode capping layer CPL may be disposed on the cathode electrode CE and may include a rare earth material that has a greater oxidizing power than an organic material for capping and the cathode electrode.

In addition, a sawing margin SM, a wafer cell edge WCE, and an insulation layer IL may be disposed between the surrounding through hole SRH and a periphery end of the bezel area BZA.

The wafer cell edge WCE may indicate the outermost portion forming a cell on a wafer substrate.

The sawing margin SM may indicate a spare portion left from the portion where the wafer substrate is cut to the wafer cell edge WCE.

The inter layer IL may include an inorganic insulating film such as silicon oxide (SiOₓ) or silicon nitride (SiNₓ). The inorganic insulating film may be deposited by a chemical vapor deposition (CVD) method of chemically depositing a layer using vapor or an atomic layer deposition (ALD) method of stacking atomic layers one by one.

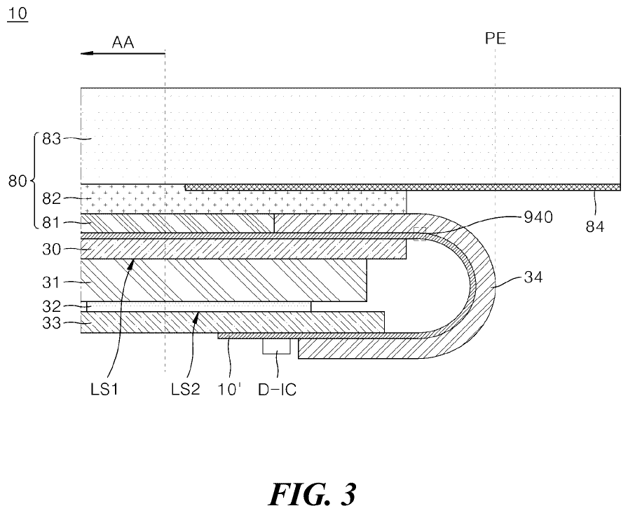

FIG. 3 is a cross-sectional view of the display device according to the embodiment of the present specification.

In other words, FIG. 3 schematically shows a cross-sectional view of an area in which the display panel 10′ of the display device 10 is bent.

Referring to FIG. 3, in the display device 10 according to the embodiment of the present specification, a first back plate 30 and a second back plate 33 for supporting the display panel 10′ are attached under the display panel 10′. The first back plate 30 may be disposed in the active area AA and a first connection part CoA1, and the second back plate 33 may be disposed to be spaced by a selected distance from the first back plate 30.

In an area in which the first back plate 30 and the second back plate 33 are spaced apart from each other, the display panel 10′ may be bent to allow a lower surface LS1 of the first back plate 30 and a lower surface LS2 of the second back plate 33 to face each other.

A fixing member 31 may be disposed under the first back plate 30. The fixing member 31 may include an adhesive and a heat-dissipation sheet and may include a metal layer capable of reflecting external light, but the embodiments of the present specification are not limited thereto.

An adhesive member 32 for connecting the fixing member 31 with the second back plate 33 may be disposed under the fixing member 31. The adhesive member 32 may be a double-sided tape, a double-sided foam adhesive tape, or a double-sided foam adhesive pad.

With respect to one support member, when the support member in the bending area BA is cut, the first back plate 30 is located above the fixing member 31 under the display panel 10′, and the second back plate 33 is located under the fixing member 31 on the rear surface portion of the display panel 10′. Here, by cutting and removing the support member in the bending area BA, the display panel 10′ is exposed from the bending area BA, and then a bending protection layer 34 and the display panel 10′ in the bending area BA are bent to be bonded to the fixing member 31 through the second back plate 33.

The first back plate 30 and the second back plate 33 may have the same height. In other embodiments, the first back plate 30 and the second back plate 33 may have different heights. In the present specification, the heights of the first back plate 30 and the second back plate 33 are not limited thereto.

The first back plate 30 and the second back plate 33 may have a strength and thickness at selected levels or more to reinforce the rigidity of the display panel 10′. Since the first back plate 30 is formed to have the strength and thickness at the selected levels or more to reinforce the rigidity of the display panel 10′, the first back plate 30 may not be formed on the display panel 10′ having a curved shape by being bent in the bending area BA. The embodiments of the present specification are not limited thereto.

Based on the shape of the display panel 10′ before bending, the second backplate BP2 may be disposed to be spaced apart from the first backplate BP1 under the display panel 10′. The second back plate 33 may be disposed under the display panel 10′ to reinforce the rigidity of the display panel 10′ and maintain the display panel 10′ in a planar state. Since the second back plate 33 is formed to have the strength and thickness at the selected levels or more to reinforce the rigidity of the display panel 10′, the second back plate BP1 may not be formed on the display panel 10′ corresponding to a portion of the bending area BA. The embodiments of the present specification are not limited thereto.

The fixing member 31 may support the surface of the display panel 10′ between the first back plate 30 and the second back plate 33. The fixing member 31 may include, for example, a metal to reinforce support strengths of the first and second back plates BP1 and BP2. In addition, the fixing member 31 may be made of a plastic material containing one or more among polycarbonate (PC), polyimide (PI), polyethylene naphthalate (PEN), and polyethylene terephthalate (PET). The embodiments of the present specification are not limited thereto. In addition, the fixing member 31 may contain one or a combination of stainless steel (SUS), glass, ceramic, and a metal.

The bending area BA of the display panel 10′ may include an area in which a partition wall 94 is disposed, and the bending protection layer 34 may be disposed to overlap the partition wall 94. The bending protection layer 34 may contain a polymer material and can prevent moisture permeation into the bending area BA.

The bending protection layer 34 may be disposed outside the display panel 10′ in the bending area BA. The bending protection layer 34 can prevent the deformation of the display panel 10′ in the bending area BA and allow the display panel 10′ to be bent at a constant curvature. The bending protection layer 34 may be formed as a resin layer to compensate the weakening of rigidity caused by bending of the display panel 10′ in the bending area BA. In addition, the bending protection layer 34 may be made of a polymer such as polyimide (PI) or polyethylene terephthalate (PET). When the bending protection layer 34 is a polymer film, the bending protection layer 34 may have the modulus of about 1 to about 10 GPa. The embodiments of the present specification are not limited thereto.

The bending protection layer 34 may include a resin, and use ultraviolet (UV) curable acrylic-based resin, but is not limited thereto. Specifically, the bending protection layer 34 may be formed of a cured product of resin subjected to the curing process after coated with the resin. When the ultraviolet curing resin is used as the resin, ultraviolet curing may be performed.

The bending protection layer 34 may be disposed outside the display panel 10′ to cover various signal lines between an encapsulation portion and pad portion of the display panel 10′. Therefore, the bending protection layer 34 can protect the signal lines from an external impact and prevent moisture permeation into the signal lines.

In addition, the bending protection layer 34 may be disposed outside the display panel 10′ in the bending area BA, thereby reinforcing the rigidity of the display panel 10′ in the bending area BA from which the support member has been removed. The bending protection layer 34 may include, for example, a micro coating layer. The micro coating layer MCL may be referred to as a micro cover layer MCL. The micro coating layer MCL may include a resin and use ultraviolet (UV) curable acrylic-based resin, but is not limited thereto. Specifically, the micro coating layer MCL may be formed of the cured product of resin subjected to the curing process after coated with the resin. When the ultraviolet curing resin is used as the resin, ultraviolet curing may be performed.

The micro coating layer MCL may be disposed outside the display panel 10′ in the bending area BA to cover various signal lines between the encapsulation portion and the pad portion of the display panel 10′. Therefore, the micro coating layer MCL can protect the signal lines from an external impact and prevent moisture permeation into the signal lines.

In addition, the micro coating layer MCL may be disposed outside the display panel 10′ in the bending area BA, thereby reinforcing the rigidity of the display panel 10′ in the bending area BA from which the support member has been removed. When the bending area BA is removed after the support member is bonded under the display panel 10′ and bent, the first back plate 30 remains under the display panel 10′, and the second back plate 33 remains above the bent display panel 10′. Therefore, although the rigidity of the display panel 10′ in the bending area BA from which the support member has been removed can be weakened, the rigidity of the bending area BA can be reinforced by the micro coating layer MCL attached to the outside.

In addition, the micro coating layer MCL may contain metal nanoparticles. The resin component is a material used when the bending protection layer 34 is formed as the micro coating layer MCL. For example, the mixed solution of the resin component and metal nanoparticles may have the thickness of about 6 μm at 10 vol % of metal nanoparticles and may be applied in the total thickness of 60 μm including the bending protection layer 34. Here, vol % is a physical unit of volume and indicates a ratio of a material to 100% of the unit volume. Therefore, 10 vol % of the metal nanoparticles indicates that metal nanoparticles account for a proportion of 10% in 100% of the mixed solution.

The micro coating layer MCL formed through the above-described process may contain metal nanoparticles and reflect ultraviolet light by the metal nanoparticles when irradiated with high-intensity ultraviolet (UV) light.

By applying the micro coating layer MCL on the display panel 10′, when irradiated with high-intensity ultraviolet (UV) light, the amount of ultraviolet light radiated to the bending area BA of the display panel 10′ can be reduced, and the rigidity near the bending area BA of the display panel 10′ can be locally reinforced. Therefore, it is possible to reduce damage to the display panel 10′ applied to the panel compared to other areas and minimize a reduction in the lifetime of the panel.

A data driver D-IC may be disposed under the display panel 10′ in a non-active area NA.

A cover window 80 may be disposed above the display panel 10′.

The cover window 80 may include an optical film 81, an adhesive 82, and an upper substrate 83. The optical film 81 may include a polarizing film POL, and the embodiments of the present specification are not limited thereto. The adhesive 82 may be formed of one or more layers made of one or more among a transparent optical clear adhesive (OCA), a transparent optical clear resin (OCR), and a pressure sensitive adhesive (PSA).

An end of the upper substrate 83 may be disposed to extend more than an end PE at which the display panel 10′ is bent. The upper substrate 83 may be disposed by applying black ink 84 to a portion corresponding to the non-active area NA to prevent light leakage from the non-active area NA of the display panel 10′.

As shown in FIG. 3, in the display device 10 according to the embodiment of the present specification, the optical film 81 may be disposed on the display panel 10′, the upper substrate 83 may be disposed on the optical film 81 through the adhesive 82, the first back plate 30 may be disposed under the display panel 10′, the fixing member 31 may be disposed under the first back plate 30, the second back plate 33 may be disposed under the fixing member 31 through the adhesive member 32, the bent display panel 10′ may be disposed under the second back plate 33, and the bending protection layer 34 may be disposed under the bent display panel 10′.

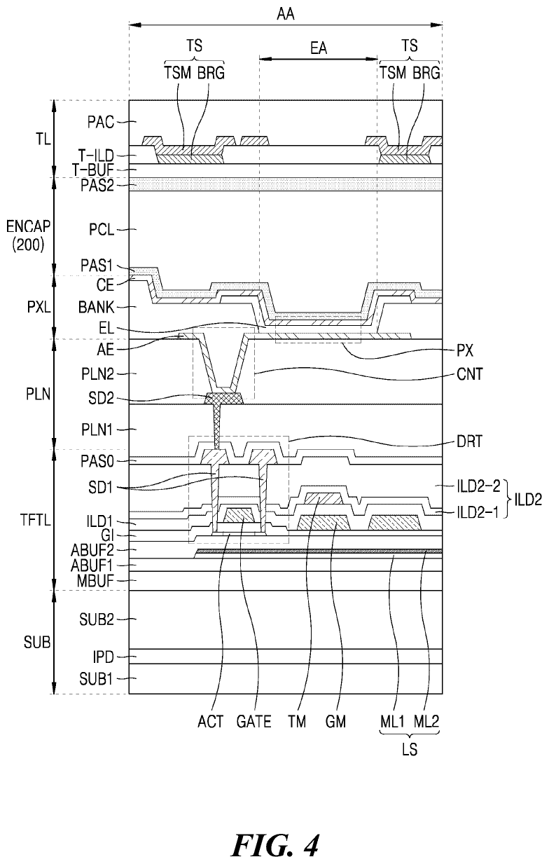

FIG. 4 is a cross-sectional view of an active area in the display device according to the embodiment of the present specification.

Referring to FIG. 4, in the active area AA of the display device 10 according to the embodiment of the present specification, a TR layer TFTL may be on a substrate SUB, a planarization layer PLN may be disposed on the TR layer TFTL, a pixel layer PXL may be disposed on the planarization layer PLN, an encapsulation layer ENCAP 200 may be disposed on the pixel layer PXL, and a touch layer TL may be disposed on the encapsulation layer ENCAP 200.

The substrate SUB may include a first substrate SUB1, an interlayer insulating film IPD, and a second substrate SUB2. The interlayer insulating film IPD may be located between the first substrate SUB1 and the second substrate SUB2. Since the substrate SUB is formed of the first substrate SUB1, the interlayer insulating film IPD, and the second substrate SUB2, it is possible to prevent moisture permeation. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

On the substrate SUB, various patterns ACT, SD1, and GATE, various insulating films MBUF, ABUF1, ABUF2, GI, ILD1, ILD2, and PAS0, and various metal patterns TM, GM, ML1, and ML2 for forming a transistor such as the driving transistor DRT may be disposed.

The TR layer TFTL may be disposed on the second substrate SUB2. In the TR layer TFTL, the multi-buffer layer MBUF may be disposed on the second substrate SUB2, and the first active buffer layer ABUF1 may be disposed on the multi-buffer layer MBUF.

The first metal layer ML1 and a second metal layer ML2 may be disposed on the first active buffer layer ABUF1. Here, the first metal layer ML1 and the second metal layer ML2 may be a light shield layer LS for shielding light.

The second active buffer layer ABUF2 may be disposed on the first metal layer ML1 and the second metal layer ML2. The active layer ACT of the driving transistor DRT may be disposed on the second active buffer layer ABUF2.

The gate insulating layer GI may be disposed to cover the active layer ACT.

The gate electrode GATE of the driving transistor DRT may be disposed on the gate insulating film GI. In this case, the gate material layer GM may be disposed on the gate insulating film GI together with the gate electrode GATE of the driving transistor DRT at a location different from a formation location of the driving transistor DRT.

The first interlayer insulating layer ILD1 may be disposed to cover the gate electrode GATE and the gate material layer GM. The metal pattern TM may be disposed on the first interlayer insulating layer ILD1. The metal pattern TM may be located at a location different from the formation location of the driving transistor DRT. The second interlayer insulating film ILD2 may be disposed to cover the metal pattern TM on the first interlayer insulating film ILD1.

Two first source-drain electrode patterns SD1 may be disposed on the second interlayer insulating layer ILD2. One of the two first source-drain electrode patterns SD1 is the source node of the driving transistor DRT, and the other is the drain node of the driving transistor DRT.

The two first source-drain electrode patterns SD1 may be electrically connected to one side and the other side of the active layer ACT through contact holes of the second interlayer insulating film ILD2, the first interlayer insulating film ILD1, and the gate insulating film GI.

The second interlayer insulating film ILD2 may include a 2-1 interlayer insulating film ILD2-1 and a 2-2 interlayer insulating film ILD2-2. The 2-1 interlayer insulating film ILD2-1 may be located to cover the metal pattern TM. The 2-2 interlayer insulating film ILD2-2 may be located on the 2-1 interlayer insulating film ILD2-1.

A portion of the active layer ACT overlapping the gate electrode GATE is a channel area. One of the two first source-drain electrode patterns SD1 may be connected to one side of the channel area in the active layer ACT, and the other of the two first source-drain electrode patterns SD1 may be connected to the other side of the channel area in the active layer ACT.

A passivation layer PAS0 may be disposed on the 2-2 interlayer insulating layer ILD2-2. The passivation layer PAS0 is disposed to cover the two first source-drain electrode patterns SD1.

A planarization layer PLN may be disposed on the passivation layer PAS0. The planarization layer PLN may include a first planarization layer PLN1 and a second planarization layer PLN2. The first planarization layer PLN1 may be disposed on the passivation layer PAS0.

A second source-drain electrode pattern SD2 may be disposed on the first planarization layer PLN1. The second source-drain electrode pattern SD2 may be connected to one (corresponding to the second node N2 of the driving transistor DRT in the sub-pixel SP of FIG. 2) of the two first source-drain electrode patterns SD1 through the contact hole of the first planarization layer PLN1.

The second planarization layer PLN2 may be disposed to cover the second source-drain electrode pattern SD2.

A light emitting element layer PXL may be disposed on the second planarization layer PLN2. Referring to the stacking structure of the light emitting element layer PXL, the light emitting element layer PXL may be disposed on the second planarization layer PLN2 of the anode electrode AE. The anode electrode AE may be electrically connected to the second source-drain electrode pattern SD2 through the contact hole of the second planarization layer PLN2.

The bank BANK may be disposed to cover a portion of the anode electrode AE. A portion of the bank BANK corresponding to an emission area EA of the sub-pixel SP may be opened.

A portion of the anode electrode AE may be exposed to an opening (opened portion) of the bank BANK. The light emitting layer EL may be located on side surfaces of the bank BANK and the opening (opened portion) of the bank BANK. All or a portion of the light emitting layer EL may be located between adjacent banks BANK.

In the opening of the bank BANK, the light emitting layer EL may be in contact with the anode electrode AE. The cathode electrode CE may be formed on the light emitting layer EL.

The light emitting element PX may be formed by the anode electrode AE, the light emitting layer EL, and the cathode electrode CE. The light emitting layer EL may include an organic film.

The encapsulation layer ENCAP 200 may be disposed on the light emitting element layer PXL.

The encapsulation layer 200 may have a single-layer structure or a multilayered structure. For example, as shown in FIG. 4, the encapsulation layer 200 may include a first encapsulation layer PAS1, a second encapsulation layer PCL (also referred to as a particle cover layer PCL in some embodiments), and a third encapsulation layer PAS2.

For example, the first encapsulation layer PAS1 and the third encapsulation layer PAS2 may be inorganic films, and the second encapsulation layer PCL may be an organic film. The second encapsulation layer PCL may be referred to as a particle cover layer PCL.

Among the first encapsulation layer PAS1, the second encapsulation layer PCL, and the third encapsulation layer PAS2, the second encapsulation layer PCL may be the thickest. Therefore, the second encapsulation layer PCL may serve as a planarization layer. The first encapsulation layer PAS1 may be referred to as a first inorganic encapsulation layer, the second encapsulation layer PCL may be referred to as an organic encapsulation layer, and the third encapsulation layer PAS2 may be referred to as a second inorganic encapsulation layer.

The first encapsulation layer PAS1 may be disposed on the cathode electrode CE and disposed closest to the light emitting element PX. The first encapsulation layer PAS1 may be made of an inorganic insulating material capable of low-temperature deposition. For example, the first encapsulation layer PAS1 may be made of silicon nitride (SiNₓ), silicon oxide (SiOₓ), silicon oxynitride (SiON), or aluminum oxide (Al₂O₃). Since the first encapsulation layer PAS1 is deposited under a low-temperature atmosphere, during the deposition process, the first encapsulation layer PAS1 can prevent damage to the light emitting layer EL containing an organic material vulnerable to a high-temperature atmosphere.

The second encapsulation layer PCL may be formed to have a smaller area than the first encapsulation layer PAS1. In this case, the second encapsulation layer PCL may be formed to expose both ends of the first encapsulation layer PAS1. The second encapsulation layer PCL may serve as a buffer for reducing stress between the layers due to bending of the display device 10 and serve to reinforce planarization performance. For example, the second encapsulation layer PCL may be made of an acrylic resin, an epoxy resin, polyimide, polyethylene, or silicon oxycarbon (SiOC) and may be made of an organic insulating material. For example, the second encapsulation layer PCL may be formed using an inkjet method.

The third encapsulation layer PAS2 may be formed to cover an upper surface and side surfaces of each of the second encapsulation layer PCL and the first encapsulation layer PAS1 on the substrate SUB which the second encapsulation layer PCL is formed. The third encapsulation layer PAS2 can minimize or block external moisture or oxygen from permeating the first encapsulation layer PAS1 and the second encapsulation layer PCL. For example, the third encapsulation layer PAS2 may be made of an inorganic insulating material such as silicon nitride (SiNₓ), silicon oxide (SiOₓ), silicon oxynitride (SiON), or aluminum oxide (Al₂O₃).

Referring to FIG. 4, the touch layer TL may be disposed on the encapsulation layer 200. When the touch layer TL is a type in which the touch sensor TS is embedded in the display panel 10′, the touch sensor TS may be disposed on the encapsulation layer 200. A structure of the touch sensor will be described in detail as follows.

A touch buffer film T-BUF may be disposed on the encapsulation layer 200. The touch sensor TS and a touch interlayer insulating layer T-ILD may be disposed on the touch buffer layer T-BUF.

The touch sensor TS may include touch sensor metals TSM and a bridge metal BRG located at different layers.

The touch interlayer insulating layer T-ILD may be disposed between the touch sensor metals TSM and the bridge metal BRG.

For example, the touch sensor metals TSM may include the first touch sensor metal TSM, the second touch sensor metal TSM, and the third touch sensor metal TSM disposed adjacent to each other. The third touch sensor metal TSM may be disposed between the first touch sensor metal TSM and the second touch sensor metal TSM, and when the first touch sensor metal TSM and the second touch sensor metal TSM are electrically connected, the first touch sensor metal TSM and the second touch sensor metal TSM may be electrically connected through the bridge metal BRG at different layers. The bridge metal BRG may be insulated from the third touch sensor metal TSM by the touch interlayer insulating layer T-ILD.

When the touch sensor TS is formed on the display panel 10′, a chemical solution (such as a developer or an etchant) used in the process may be introduced, or external moisture may be introduced. By arranging the touch sensor TS on the touch buffer film T-BUF, it is possible to prevent a chemical solution, moisture, etc., from permeating the light emitting layer EL containing an organic material during the manufacturing process of the touch sensor TS. Therefore, the touch buffer film T-BUF can prevent damage to the light emitting layer EL vulnerable to a chemical solution or moisture.

The touch buffer film T-BUF is made of an organic insulating material that may be formed at low temperatures smaller than a selected temperature (e.g., 100° C.) and has a low dielectric constant of 1 to 3 to prevent damage to the light emitting layer EL containing an organic material vulnerable to high temperatures. For example, the touch buffer film T-BUF may be made of an acrylic-based, epoxy-based, or siloxan-based material. As the display device 1 is bent, the encapsulation layer ENCAP may be damaged, and the touch sensor metal located on the touch buffer film T-BUF may be broken. Even when the display device 10 is bent, the touch buffer film T-BUF made of an organic insulating material and having planarization performance can prevent the damage to the encapsulation layer 200 and/or the breakage of the metals TSM and BRG forming the touch sensor TS.

The protective layer (PAC) may be disposed on the touch sensor TS and the touch interlayer insulating layer T-ILD. The protective layer PAC may be disposed to cover the touch sensor TS. The protective layer PAC may be made of an organic material.

Meanwhile, the encapsulation layer 200 according to the embodiment of the present specification may be formed on the display panel 10′ by a manufacturing device. The manufacturing device may include a resin application valve (Jet valve) and an application nozzle. Therefore, a process of forming the encapsulation layer 200 may be performed in a state in which a chip on film (COF), a flexible printed circuit board (FPCB), a FPC top liner, etc., are disposed.

The encapsulation layer 200 may be formed by applying a mixed solution of a resin component and aluminum (Al) nanoparticles through the application nozzle in a state in which the resin application valve is located at the end of the second display panel 10′.

The resin component is a material used when the bending protection layer 34 is formed as the micro coating layer MCL. The mixed solution of the resin component and the aluminum nanoparticles may have the thickness of 10 to 30 nm of the aluminum nanoparticles at 10 vol % and may be applied in the total thickness of 60 nm. Here, vol % is a physical unit of volume and indicates a ratio of a material to 100% of the unit volume. Therefore, 10 vol % of the aluminum nanoparticles indicates that aluminum nanoparticles account for a proportion of 10% in 100% of the mixed solution.

The encapsulation layer 200 formed by the above-described process may include aluminum (Al) nanoparticles to reflect ultraviolet (UV) light when irradiated with ultraviolet light.

Here, the aluminum nanoparticles were found to have a higher ultraviolet reflectance than other metal nanoparticles. The aluminum nanoparticles were found to be 0.9 when the wavelength (λ) of ultraviolet light was 350 nm. Therefore, it can be seen that aluminum has a higher reflectance than other metals when irradiated with ultraviolet light having the same wavelength.

The mixed solution of the resin component and the aluminum nanoparticles is a composite material of a resin and a metal, and with respect to ultraviolet light having the wavelength (λ) of 350 nm, 90% of the amount of ultraviolet light radiated to the encapsulation layer 200 may be reflected by the reflectance of the aluminum nanoparticles.

When the mixed solution of the resin component and the aluminum nanoparticles was a composite material and applied on the bending protection layer 34 or the display panel 10′ in the thickness of 60 nm, it was found that the values of the reflectance and the modulus were high when the aluminum nanoparticles are precipitated at 10 vol % in the mixed solution. When the aluminum nanoparticles are precipitated in the thickness of 6 nm or less, which is 10 vol % of the total thickness of 60 nm of the encapsulation layer 200, the ultraviolet reflectance is shown to be about 90%, and the modulus is shown to be about 1,625 MPa.

As described above, by forming the bending protection layer 34 and the encapsulation layer 200 outside the bent portion of the display panel 10′ in the bending area BA and reflecting ultraviolet light through the metal nanoparticles when irradiated with the ultraviolet light, it is possible to prevent cracks in and damage to the panel.

In addition, when the display panel 10′ is manufactured, ultraviolet radiation may be locally controlled through the amount of precipitation of metal nanoparticles contained in the encapsulation layer 200 in the bending area BA vulnerable to ultraviolet radiation.

In addition, when the display panel 10′ is manufactured, by reflecting the ultraviolet light through the metal nanoparticles contained in the encapsulation layer 200, it is possible to reinforce the compression rigidity of the bending area BA of the display panel 10′.

Meanwhile, the driving integrated circuit D-IC may be disposed on the other surface of the pad portion of the display panel 10′.

The driving integrated circuit D-IC may be mounted on the display panel 10′ by a chip bonding process or a surface mounting process. Based on the bent state, the driving integrated circuit D-IC may be disposed under the display panel 10′. For example, the driving integrated circuit D-IC may be disposed under the pad portion.

In this case, a flexible printed circuit board (not shown) may be disposed between the pad portion PAD and the driving integrated circuit D-IC, and the driving integrated circuit D-IC may be located on a back surface of the flexible printed circuit board (FPCB).

The driving integrated circuit D-IC generates a data signal and a gate control signal based on image data and timing synchronization signals supplied from an external host driving system. In addition, the driving integrated circuit D-IC may supply the data signal to a data line of each pixel through the pad portion and supply the gate control signal to a gate driver 13.

The driving integrated circuit D-IC may be mounted on a chip mounting area defined in the display panel 10′ and electrically connected to the pad portion, and may be connected to each of the gate driver and a signal line of a pixel array unit that are disposed on the display panel 10′.

Since the driving integrated circuit D-IC generates considerable heat, it is necessary to effectively dissipate heat from the driving integrated circuit D-IC. The driving integrated circuit D-IC may be primarily heat-dissipated by a support plate.

The pad portion may be disposed on one side portion of the display panel 10′ on which the driving integrated circuit D-IC is mounted. The pad portion may be electrically connected to the FPCB on which the circuit board is mounted on the rear surface of the display panel 10′.

One side of the FPCB may be electrically connected to the pad portion provided on the one side portion of the display panel 10′ by a film attachment process using a conductive adhesive layer and may be located on the back surface of the display panel 10′.

In this case, the conductive adhesive layer may use, for example, an anisotropic conductive film (ACF).

A circuit board may provide the image data and the timing synchronization signals that are supplied from the host driving system to the driving integrated circuit and provide voltages required to drive each of the pixel array unit, a gate driving circuit unit, and a driving integrated circuit.

The FPCB of which one side is connected to the display panel 10′ may be formed to extend to be bent to the back surface of the front surface portion of the display panel 10′ together with the display panel 100.

The FPCB extending from one side connected to the display panel 10′ may be located on the back surface of the display panel 10′ not covered by the pad portion of the display panel 10′.

Therefore, at least a portion of the FPCB may be in contact with the back surface of the display panel 10′.

The display device 10 according to the embodiment of the present specification indicates a flexible display device and may be used with the same meaning as a bendable display device, a rollable display device, an unbreakable display device, a foldable display device, etc.

The driving integrated circuit D-IC may be implemented by a thin film transistor TFT in the non-active area NA. The driving integrated circuit D-IC may be referred to as a gate-in-panel (GIP) circuit unit. The GIP circuit unit GIP may include a gate driver having a GIP structure, and in this case, the gate driver is formed of a bottom gate type thin film transistor BG-T, and source and drain metal films of a bridge line may extend and may be connected to a drain electrode of the BG thin film transistor.

In addition, some components such as the driving integrated circuit D-IC may be mounted on separated printed circuit boards and may be coupled to connection interfaces (pads/bumps, pins, etc.) disposed in the non-active area NA using a circuit film such as a FPCB, a chip-on-film (COG), or a tape-carrier-package (TCP). Since the non-active area NA may be bent together with the connection interface, the printed circuit (COF, PCB, etc.) may be located on the rear surface (or the back surface) of the display device 1.

The display device 10 according to the present specification may include various additional elements for generating various signals or driving pixels PX in the active area. Additional elements for driving the pixels may include an inverter circuit, a multiplexer, an electrostatic discharge circuit, etc. The display device 10 according to the present specification may also include additional elements associated with functions other than pixel driving. For example, the display device 10 according to the present specification may include additional elements for providing a touch detection function, a user authentication function (e.g., fingerprint recognition), a multi-level pressure detection function, a tactile feedback function, etc. The above-described additional elements may be located in the non-active area NA and/or an external circuit connected to the connection interface.

Various parts of the display device 10 according to the present specification may be bent along a bending line. The bending line may extend horizontally, vertically, or diagonally. Therefore, the display device 10 according to the embodiment of the present specification may be bent in a combination of horizontal, vertical, and diagonal directions based on a required design.

One or more edges of the display device 10 according to the present specification may be bent away from a central portion along the bending line. The bending line may be located close to the edge of the display device 10, but may extend across the central portion or extend diagonally from one or more corners of the display device 10. Such a structure may allow the display device 10 to be a foldable display device or a display device for displaying images on both folded surfaces.

Since one or more portions of the display device 10 may be bent, the display device 10 according to the present specification can be defined as a substantially flat portion and a bent portion. A portion of the display device 10 may be referred to as a substantially flat planar area. A portion of the display device 10 may be bent at a selected angle, and such a portion may be referred to as a bending area or a curvature area. The curvature area includes a bent section that is actually bent with a selected bending radius.

The term “substantially flat” also includes a portion that are not perfectly flat. For example, a concave central portion and a convex central portion may also be described as substantially flat portions in some embodiments. One or more bent portions are present next to the concave central portion or the convex central portion and are bent inward or outward at an angle with respect to a bending axis along the bending line. A bending radius of the curvature area is smaller than a bending radius of the flat area. In other words, the term “substantially flat portion” indicates a portion that has a smaller curvature than adjacent sections.

According to the location of the bending line, while a portion at one side of the bending line is located toward the center of the display device 10, a portion at the other side of the bending line is located toward the edge of the display device 10. The portion disposed toward the center of the display device 10 may be described as a central portion, and the portion located toward the edge of the display device 10 may be described as an edge portion. In some cases, the central portion of the display device 10 may be substantially flat and the edge portion thereof may be a bent portion. The substantially flat portion may also be located on the edge portion. In addition, in some shapes of display device 10, the bent section may be disposed between two substantially flat portions.

When the non-active area NA is bent, the non-active area NA may be invisible or only minimally visible from the front surface of the display device 10. A portion of the non-active area NA visible from the front surface of the display device 10 may be covered by a bezel. The bezel may be a stand-alone structure or may be formed of a housing or other suitable elements. The portion visible from the front surface of the display device 10 of the non-active area NA may be hidden under an opaque mask layer such as black ink (e.g., polymer filled with carbon black). Such an opaque mask layer may be provided on any layer (a touch sensor layer, a polarizing layer, a particle cover layer, etc.) included in the display device 10.

In some embodiments, the bent portion of the display device 10 may include the active area in which images may be displayed. In other words, the bending line may be disposed in the active area so that at least some pixels of the active area are included in the bent portion.

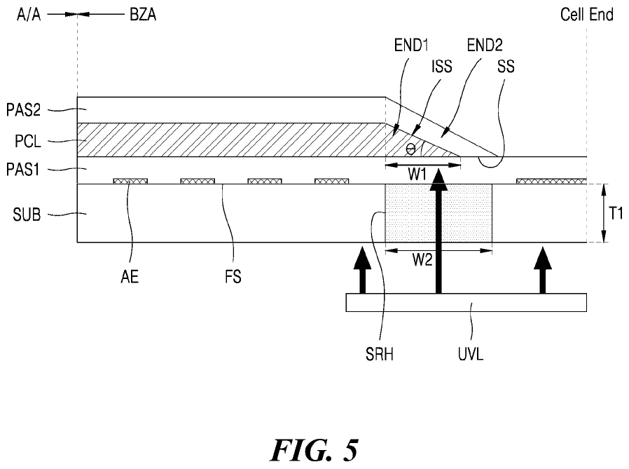

FIG. 5 is a view showing an example in which a particle cover layer PCL is cured through a surrounding through hole according to the embodiment of the present specification.

Referring to FIG. 5, the surrounding through hole SRH according to the embodiment of the present specification may be formed in the wafer substrate WSUB in the bezel area BZA. In other words, the surrounding through hole SRH may be formed in the wafer substrate WSUB including the display panel 10′.

Although not shown in the drawing, the wafer substrate WSUB may include the substrate SUB and the planarization layer PLN in the non-active area NA and include the substrate SUB, the TR layer TFTL, the planarization layer PLN, and the pixel layer PXL in the active area AA. The wafer substrate WSUB may have a first thickness T1 to include the substrate SUB, the TR layer TFTL, the planarization layer PLN, and the pixel layer PXL.

In FIG. 5, one or more anode electrode AE patterns may be disposed on the wafer substrate WSUB.

The encapsulation layer ENCAP 200 may be disposed on the wafer substrate WSUB and the one or more anode electrode AE patterns. In other words, the first encapsulation layer PAS1 may be disposed on the wafer substrate WSUB and the one or more anode electrode AE patterns, the second encapsulation layer PCL may be disposed on the first encapsulation layer PAS1, and the third encapsulation layer PAS2 may be disposed on the second encapsulation layer PCL.

When the resin component is applied on the first encapsulation layer PAS1 to flow toward the cell end using the inkjet method in the manufacturing process, the second encapsulation layer PCL is formed by radiating ultraviolet (UV) light emitted by an ultraviolet supply device UVL to the resin component through the surrounding through hole SRH and curing the resin component. Therefore, the end (or an end portion) END1 of the second encapsulation layer PCL may be located at a location corresponding to the surrounding through hole SRH. In some embodiments, the end END1 of the second encapsulation layer PCL overlaps with the surrounding through hole SRH from a plan view. In some embodiments, the surrounding through hole SRH have therein a transparent material.

The second encapsulation layer PCL may be made of an organic insulating material such as an acrylic resin, an epoxy resin, polyimide, polyethylene, or silicon oxycarbon (SiOC).

As shown in FIG. 5, the surrounding through hole SRH may be formed in the wafer substrate WSUB between the anode electrode AE pattern located at the cell end and the anode electrode AE pattern next located therefrom in the bezel area BZA.

In some embodiments, the surrounding through hole SRH extends through the wafer substrate WSUB.

As illustrated, the first encapsulation layer PAS1 is on the wafer substrate WSUB. The first encapsulation layer PAS1 has a first surface FS and a second surface SS opposite the first surface FS. The second encapsulation layer PCL is on the second surface SS of the first encapsulation layer PAS1. As shown, the second encapsulation layer PCL has an end portion END1 having a triangular cross-section with an inclined side surface ISS. However, the shape of the end portion END1 is not limited to the shape as shown in FIG. 5 and can have various different type of shapes. Here, as illustrated, the end portion END1 of the second encapsulation layer PCL overlaps with the surrounding through hole SRH from a plan view.

Further, the end portion END1 of the second encapsulation layer PCL has an inclination angle θ between the inclined side surface ISS and the second surface SS of the first encapsulation layer PAS1.

In some embodiments, the end portion END1 of the second encapsulation layer PCL fully overlaps with the surrounding through hole SRH from a plan view. For example, a width W1 of the end portion END1 of the second encapsulation layer PCL as shown in FIG. 5 may be smaller than a width W2 of surrounding through hole SRH such that the end portion END1 of the second encapsulation layer PCL fully overlaps with the surrounding through hole SRH from a plan view.

In addition, the third encapsulation layer PAS2 is disposed on the second encapsulation layer PCL. The third encapsulation layer also has an end portion END2 and the end portion END2 of the third encapsulation layer PAS2 is on and covers the end portion END1 of the second encapsulation layer PCL. In some embodiments, the end portion END2 of the third encapsulation layer PAS2 overlaps with the surrounding through hole SRH from a plan view.

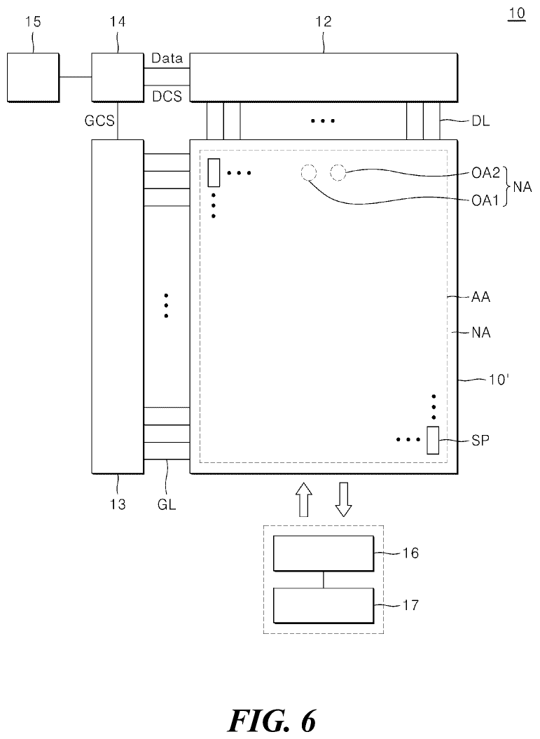

FIG. 6 is a block diagram schematically showing a systematic configuration of the display device according to the embodiment of the present specification.

Referring to FIG. 6, the display device 10 according to the embodiment of the present specification may include the display panel 10′ and a display driving circuit.

The display driving circuit is a circuit for driving the display panel 10′ and may include a data driver 12, a gate driver 13, a controller 14, etc.

The display panel 10′ may include the active area AA in which images are displayed and the non-active area NA in which the images are not displayed. The non-active area NA may be an area outside the active area AA and is also referred to as the bezel area BZA. All or a portion of the non-active area NA may be an area visible from the front surface of the display device 10 or may be an area bent and not visible from the front surface of the display device 10.

The display panel 10′ may include the substrate SUB and a plurality of sub-pixels SP disposed on the substrate SUB. In addition, the display panel 10′ may further include various types of signal lines to drive the plurality of sub-pixels SP.

The display device 10 according to the embodiments of the present specification may be a liquid crystal display, etc., or a light emitting display device in which the display panel 10′ itself emits light. When the display device 10 according to the embodiments of the present specification is a self-luminous display device, each of the plurality of sub-pixels SP may include the light emitting element PX.

For example, the display device 10 according to the embodiments of the present specification may be an organic light emitting diode display device in which the light emitting element PX is implemented as the organic light emitting diode (OLED). For another example, the display device 10 according to the embodiments of the present specification may be an inorganic light emitting display device in which the light emitting element is implemented as an inorganic material-based light emitting diode. For still another example, the display device 10 according to the embodiments of the present specification may be a quantum dot display device in which the light emitting element is implemented as quantum dots that are semiconductor crystals emitting light by themselves.

The structure of each sub-pixel SP may be changed depending on the type of display device 10. For example, when the display device 10 is a self-luminous display device in which the sub-pixels SP emit light by themselves, each sub-pixel SP may include a light emitting element that emits light by itself, one or more transistors, and one or more capacitors.

For example, various types of signal lines may include a plurality of data lines DL through which data signals (referred to as data voltages or image signals) are transmitted, a plurality of gate lines GL through which gate signals (referred to as scan signals) are transmitted, etc.

The plurality of data lines DL and the plurality of gate lines GL may intersect each other. Each of the plurality of data lines DL may be disposed to extend in a first direction. Each of the plurality of gate lines GL may be disposed to extend in a second direction.

Here, the first direction may be a column direction, and the second direction may be a row direction. The first direction may be the row direction, and the second direction may be the column direction.

The data driver 12 is a circuit configured to drive the plurality of data lines DL and may output the data signals to the plurality of data lines DL. The data driver 12 may supply the data voltages to the display panel 100.

The gate driver 13 is a circuit configured to drive the plurality of gate lines GL and may output the gate signals to the plurality of gate lines GL. The gate driver 13 may supply the gate signals to the display panel 100.

The controller 14 may be a device configured to control the data driver 12 and the gate driver 13. The controller 14 may control the driving timing for the plurality of data lines DL and the driving timing for the plurality of gate lines GL.

The controller 14 may supply a data driving control signal DCS to the data driver 12 to control the data driver 12. The controller 14 may supply a gate driving control signal GCS to the gate driver 13 to control the gate driver 13.

The controller 14 may receive input image data from a host system 15 and supply image data Data to the data driver 12 based on the input image data.

The data driver 12 may supply data signals to the plurality of data lines DL according to the driving timing control of the controller 14.

The data driver 12 may receive the digital image data Data from the controller 14, convert the received image data Data into analog data signals, and output the analog data signals to the plurality of data lines DL.

The gate driver 13 may supply the gate signals to the plurality of gate lines GL according to the timing control of the controller 14. The gate driver 13 may receive a first gate voltage corresponding to a turn-on level voltage and a second gate voltage corresponding to a turn-off level voltage together with various gate driving control signals GCS, generate the gate signals, and supply the generated gate signals to the plurality of gate lines GL.

For example, the data driver 12 may be connected to the display panel 10′ using a tape automated bonding (TAB) method, connected to a bonding pad of the display panel 10′ using a chip on glass (COG) or chip on panel (COP) method, or connected to the display panel 10′ using a chip on film (COF) method.

The gate driver 13 may be connected to the display panel 10′ using the TAB method, connected to the bonding pad of the display panel 10′ using the COG or COP method, or connected to the display panel 10′ using the COF method. Alternatively, the gate driver 13 may be formed in the non-active area NA of the display panel 10′ in a gate in panel (GIP) type. The gate driver 13 may be disposed on the substrate SUB or connected to the substrate SUB. In other words, when the gate driver 13 is the GIP type, the gate driver 13 may be disposed in the non-active area NA of the substrate SUB. The gate driver 13 may be connected to the substrate when the gate driver 13 is the COG type, the COF type, etc.

Meanwhile, a driving circuit of at least one of the data driver 12 and the gate driver 13 may be disposed in the active area AA of the display panel 10′. For example, the driving circuit of at least one of the data driver 12 and the gate driver 13 may be disposed not to overlap the sub-pixels SP and may be disposed to partially or entirely overlap the sub-pixels SP.

The data driver 12 may be connected to one side (e.g., upper side or lower side) of the display panel 10′. The data driver 12 may be connected to both sides (e.g., upper and lower sides) of the display panel 10′ or connected to two or more side surfaces among four side surfaces of the display panel 10′ according to a driving method, a panel design method, etc.

The gate driver 13 may be connected to one side (e.g., left side or right side) of the display panel 10′. The gate driver 13 may be connected to both sides (e.g., left and right sides) of the display panel 10′ or connected to two or more side surfaces among four side surfaces of the display panel 10′ according to a driving method, a panel design method, etc.

The controller 14 may be implemented as a component separately from the data driver 12 or implemented as an integrated circuit by being integrated with the data driver 12.

The controller 14 may be a timing controller used in a typical display technology, a control device capable of further performing other control functions other than the timing controller, a control device different from the timing controller, or a circuit in the control device. The controller 14 may be implemented as various circuits or electronic components, such as an integrated circuit (IC), a field programmable gate array (FPGA), an application specific integrated circuit (ASIC), and a processor.

The controller 14 may be electrically connected to the data driver 12 and the gate driver 13 through a PCB, a FPCB, etc.

The controller 14 may transmit and receive signals to and from the data driver 12 according to one or more selected interfaces. Here, for example, the interface may include a low voltage differential signaling (LVDS) interface, an embedded panel interface (EPI), a serial peripheral interface (SPI), etc.

Referring to FIG. 6, the display device 10 according to the embodiments of the present specification may include one or more open areas OA in which at least a portion of the substrate SUB has been removed.

One or more electro-optical devices (not shown) may be disposed in an area whose at least a portion overlaps the open area OA. The one or more electro-optical devices may include, for example, one or more of a photographing device such as a camera (image sensor), a detection sensor such as a proximity sensor, and an illuminance sensor, etc.

For example, the photographing device such as a camera may be located under a first open area OA1, and the detection sensor may be located under the first open area OA1 in a second open area OA2.

The electro-optical device may be located under the substrate SUB, and at least a portion of the electro-optical device may be located to overlap the open area OA.

The first open area OA1 and the second open area OA2 may have various shapes, such as a circular, elliptical, quadrangular, hexagonal, or octagonal shape. The shapes of the first open area OA1 and the second open area OA2 may be the same or different. An area of the first open area OA1 may be the same as or different from an area of the second open area OA2.

For convenience of description, it is assumed that the first open area OA1 and the second open area OA2 have a circular shape and have the same area, but the present disclosure is not limited thereto.

Meanwhile, one or more open areas OA may be located in an area in which the substrate SUB has been removed, and the open areas OA may be the non-active area NA in which the sub-pixel SP is not disposed.

The open area OA located in the active area AA is also referred to as a “hole in active area (HiAA).”

The signal lines (e.g., the data lines DL and the gate lines GL) disposed on the substrate SUB may be disposed near (or bypassing) the open area OA.

To provide both an image display function and a touch sensing function, the display device 10 according to the embodiments of the present specification may include a touch sensor, and a touch sensing circuit for detecting whether touch has been caused by a touch object such as a finger or a pen or detecting a touch location by sensing the touch sensor.

The touch sensing circuit may include a touch driving circuit 16 for driving and sensing the touch sensor and generating and outputting touch sensing data, a touch controller 17 for sensing the occurrence of touch or detecting the touch location using the touch sensing data, etc.

The touch sensor may include a plurality of touch electrodes. The touch sensor may further include a plurality of touch lines for electrically connecting a plurality of touch electrodes with the touch driving circuit 16.

The touch sensor may be present outside the display panel 10′ in the form of a touch panel or present inside the display panel 10′.

When the touch sensor is present outside the display panel 10′ in the form of a panel, the touch sensor is referred to as an external type touch sensor. When the touch sensor is an external type, the touch panel and the display panel 10′ may be manufactured separately and coupled during the assembly process. The external type touch panel may include a touch panel substrate and a plurality of touch electrodes disposed on the touch panel substrate.

When the touch sensor is present inside the display panel 10′, the touch sensor may be formed on the substrate SUB together with signal lines, electrodes, etc., related to display driving during the manufacturing process of the display panel 10′.

The touch driving circuit 16 may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

When the touch sensing circuit performs touch sensing using the self-capacitance sensing method, the touch sensing circuit may perform the touch sensing based on a capacitance between each touch electrode and the touch object (e.g., a finger or a pen).

According to the self-capacitance sensing method, each of the plurality of touch electrodes may serve as both a driving touch electrode and a sensing touch electrode. The touch driving circuit 160 may drive all or some of the plurality of touch electrodes and sense all or some of the plurality of touch electrodes.

When the touch sensing circuit performs the touch sensing using the mutual-capacitance sensing method, the touch sensing circuit may perform the touch sensing based on the capacitance between the touch electrodes.

According to the mutual-capacitance sensing method, the plurality of touch electrodes are divided into driving touch electrodes and sensing touch electrodes. The touch driving circuit 16 may drive the driving touch electrodes and sense the sensing touch electrodes.

The touch driving circuit 16 and touch controller 17 included in the touch sensing circuit may be implemented as separate devices or implemented as a single device. In addition, the touch driving circuit 16 and the data driver 12 may be implemented as separate devices or implemented as a single device.

The display device 10 may further include a power supply circuit for supplying various types of power to the display driving circuit and/or the touch sensing circuit, etc.

The display device 10 according to the embodiments of the present specification may be a mobile terminal such as a smartphone or a tablet, a monitor or a TV having various sizes, etc., and is not limited thereto, and may be a display device having various types and sizes, which may display information or images.

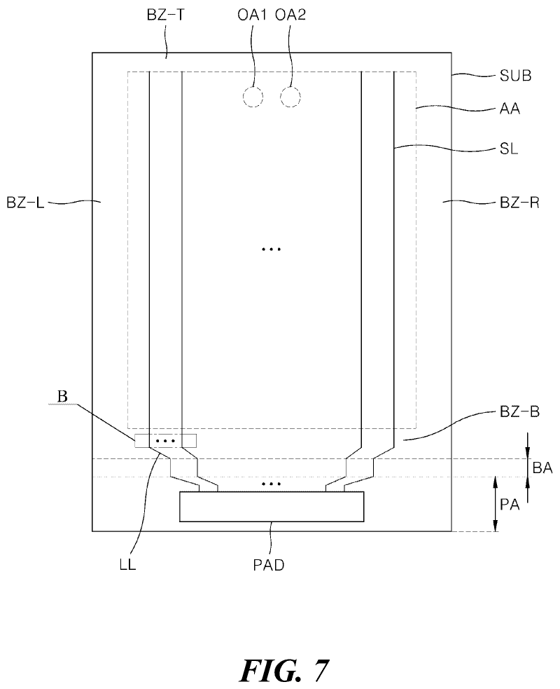

FIG. 7 is a view showing an active area, a bending area, and a pad area in a display panel according to the embodiment of the present specification.

Referring to FIG. 7, the display panel 10′ according to embodiments of the present specification includes the active area AA and a non-active area around the active area AA.

The non-active area may include open areas OA1 and OA2, a bezel area BZA, a bending area BA, a pad area PA, etc.

In the active area AA, a number of sub-pixels for displaying images are located. In addition, one or more signal lines SL are disposed in the active area AA.

The signal line SL may include a data line through which a data signal is supplied to the sub-pixel, and a gate signal through which a gate signal is supplied to the sub-pixel.

The signal line SL shown in FIG. 7 may include a touch sensor embedded in the display panel 10′. For example, a touch driving signal output from a touch driving circuit may be input to the signal line SL.

Hereinafter, the signal line SL will be described assuming that it is a data line through which the data signal is supplied to the sub-pixel, but is not limited thereto.

Referring to FIG. 7, the bezel area is located near the active area AA. For example, a top bezel BZ-T may be located at a top side of the active area AA, a left bezel BZ-L may be located at a left side of the active area AA, a right bezel BZ-R may be located at a right side of the active area AA, and a bottom bezel BZ-B may be located at a bottom side of the active area AA.

For example, in the left bezel area and/or the right bezel area, a gate driving circuit may be disposed in the GIP type, or the gate driving circuit may be disposed in the COG type, the COF type, etc.

In the top bezel area and/or the bottom bezel area, a data driving circuit may be connected to the display panel 10′ using the TAB method. Alternatively, at the pad portion PAD, the data driving circuit may be connected to the display panel 10′ using the COG method or the COP method. Alternatively, the data driving circuit may be implemented using the COF method and connected to the display panel 10′ in the bezel area.

In FIG. 7, the bending area BA and the pad area PA are marked separately from the bottom bezel BZ-B to distinguish the bending area BA from the pad area PA. However, the bending area BA and the pad area PA may be included in the bottom bezel BZ-B. In the present specification, for convenience of description, the bottom bezel BZ-B and the bending area BA are separately described, but the display device according to the embodiments of the present specification is not limited thereto.

Referring to FIG. 7, the bending area BA and the pad area PA in which the pad portion PAD is located may be located under the bottom bezel BZ-B.

The substrate constituting the display panel 10′ is bent in the bending area BA, and the pad area PA is located toward a back surface of the active area AA.

In the bending area BA, a plurality of link lines LL for electrically connecting the pad portion PAD with the signal lines SL are disposed.

The plurality of link lines LL is disposed in a direction perpendicular to a bending axis in the bending area BA. The plurality of link lines LL may be disposed in a diagonal direction inclined from a vertical direction at at least one of the top and bottom sides of the bending area BA.

The pad portion PAD may transmit a signal input from the outside to the signal line SL or include at least one pin for transmitting a signal input from the signal line SL to the outside.

For example, when the signal line SL is a data line, the pad portion PAD is connected to the data driving circuit, and the pad portion is electrically connected to the data lines in the active area AA through the plurality of link lines LL.

When the data driving circuit is located using the COP method, the data driving circuit may be located on the pad portion PAD.

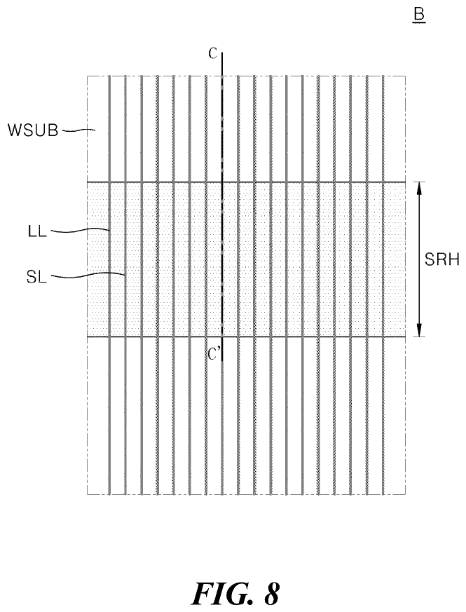

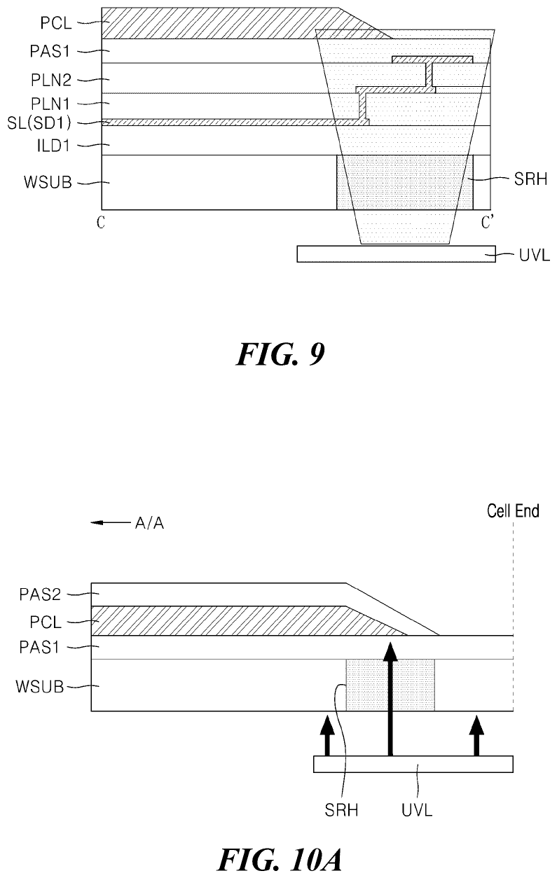

FIG. 8 is a view showing a structure of area B in FIG. 7 in the display device according to the embodiment of the present specification. FIG. 9 is a cross-sectional view along line C-C′ in FIG. 8 in the display device according to the embodiment of the present specification.

Referring to FIG. 8, the wafer substrate WSUB according to the embodiment of the present specification may be disposed so that the plurality of link lines LL, signal lines SL, etc., pass over the surrounding through hole SRH formed therein.

Referring to FIG. 9, the surrounding through hole SRH may be formed in the wafer substrate WSUB in the bezel area BZA.

In addition, a first insulating layer ILD1 may be disposed on the wafer substrate WSUB, and the signal line SL may be disposed on the first insulating layer ILD1. Here, the signal line SL may be formed of a first source-drain line SD1.

In addition, a first planarization layer PLN1 may be disposed on the signal line SL, a second planarization layer PLN2 may be disposed on the first planarization layer PLN1, and a first encapsulation layer PAS1 may be disposed on the second planarization layer PLN2.

In addition, the second encapsulation layer PCL may be disposed on the first encapsulation layer PAS1.

An end of the second encapsulation layer PCL may be located at a location corresponding to the surrounding through hole SRH. For example, in the manufacturing process, the second encapsulation layer PCL may be cured by ultraviolet light radiated from the ultraviolet supply device UVL through the surrounding through hole SRH, and the end of the second encapsulation layer PCL may be formed at the location corresponding to the surrounding through hole SRH.

The signal line SL may be electrically connected to a connection electrode on the first planarization layer PLN1 and a connection electrode on the second planarization layer PLN2 via contact holes at the location corresponding to the surrounding through hole SRH.

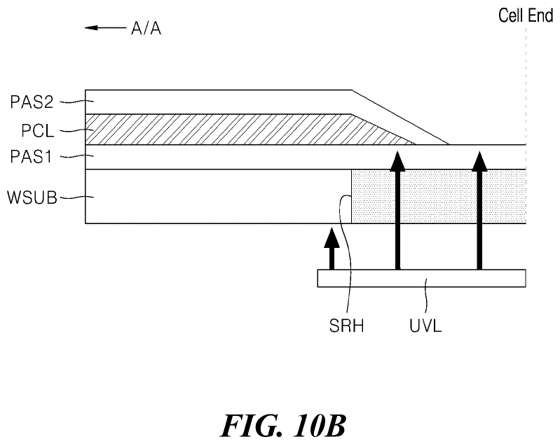

FIGS. 10A and 10B are views showing an example in which the PCL is cured by light radiated through a surrounding through hole of a wafer substrate in a process of manufacturing the display device according to the embodiment of the present specification.

Referring to FIG. 10A, the surrounding through hole SRH according to the embodiment of the present specification may be formed in the wafer substrate WSUB.

The first encapsulation layer PAS1 may be disposed on the wafer substrate SUB, the second encapsulation layer PCL may be disposed on the first encapsulation layer PAS1, and the third encapsulation layer PAS2 may be disposed on the second encapsulation layer PCL.

In this case, the surrounding through hole SRH may be spaced by a selected distance from the periphery end of the bezel area BZA and formed in the wafer substrate WSUB.

Therefore, the ultraviolet light supplied from the ultraviolet supply device UVL disposed under the wafer substrate WSUB may be radiated to the second encapsulation layer PCL through the surrounding through hole SRH.

Therefore, the second encapsulation layer PCL moving on the first encapsulation layer PAS1 during the manufacturing process may cured by the ultraviolet light radiated through the surrounding through hole SRH, and the end of the second encapsulation layer PCL may be formed by being stopped at the location corresponding to the surrounding through hole SRH.

The end of the second encapsulation layer PCL may be formed to be inclined at the location corresponding to the surrounding through hole SRH.

Referring to FIG. 10B, the surrounding through hole SRH according to the embodiment of the present specification may be formed from the periphery end of the bezel area BZA to a location at which the inclined end of the second encapsulation layer PCL starts.

Therefore, since the surrounding through hole SRH shown in FIG. 10B has a greater width than the surrounding through hole SRH shown in FIG. 10A, a larger amount of ultraviolet light may pass through the second encapsulation layer PCL to cure the second encapsulation layer PCL more quickly.

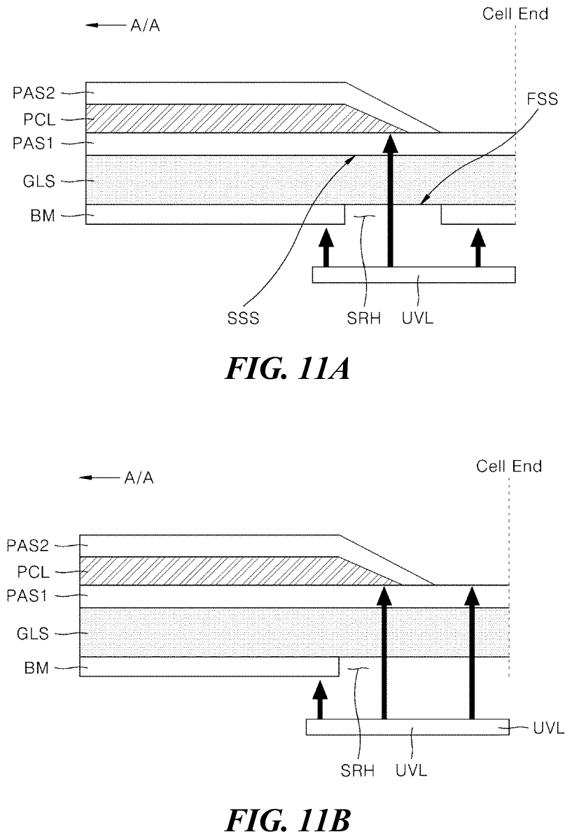

FIGS. 11A and 11B are views showing an example in which the PCL is cured by light radiated through a surrounding through hole of a black matrix in the process of manufacturing the display device according to the embodiment of the present specification.

Referring to FIG. 11A, the surrounding through hole SRH passing through the display panel 10′ in the display device according to the embodiment of the present specification may be formed in a black matrix BM.

The glass substrate GLS (or glass layer GLS) may be disposed on the black matrix BM, the first encapsulation layer PAS1 may be disposed on the glass layer GLS, the second encapsulation layer PCL may be disposed on the first encapsulation layer PAS1, and the third encapsulation layer PAS2 may be disposed on the second encapsulation layer PCL.

In this case, the surrounding through hole SRH may be spaced by a selected distance from the periphery end of the bezel area BZA and formed in the black matrix BM.

Therefore, the ultraviolet light supplied from the ultraviolet supply device UVL disposed under the black matrix BM may be radiated to the second encapsulation layer PCL through the surrounding through hole SRH.

Therefore, the second encapsulation layer PCL moving on the first encapsulation layer PAS1 during the manufacturing process may cured by the ultraviolet light radiated through the surrounding through hole SRH, and the end of the second encapsulation layer PCL may be formed by being stopped at the location corresponding to the surrounding through hole SRH.

In this case, the end of the second encapsulation layer PCL may be formed to be inclined at the location corresponding to the surrounding through hole SRH.

Referring to FIG. 11A, the glass layer GLS has a first surface FSS and a second surface SSS opposite the first surface FSS. The black matrix BM is disposed on the first surface FSS of the glass layer GLS.

In some embodiments, the surrounding through hole SRH extends through the black matrix BM and exposes the first surface FSS of the glass layer GLS.

As illustrated, the first encapsulation layer PAS1 on the second surface SSS of the glass layer GLS. The second encapsulation layer PCL is on the first encapsulation layer PAS1 and the second encapsulation layer has an end portion. The end portion of the second encapsulation layer PCL overlaps with the surrounding through hole SRH from a plan view.

In addition, the third encapsulation layer PAS2 is disposed on the second encapsulation layer PCL. Similar descriptions regarding the end portions of the second encapsulation layer PCL, the third encapsulation layer PAS2 described in connection with FIG. 5 will not be repeated.

In some embodiments, the end portion of the third encapsulation layer PAS2 is on and covers the end portion of the second encapsulation layer PCL. Here, the end portion of the third encapsulation layer PAS2 overlaps with the surrounding through hole SRH from a plan view.

Referring to FIG. 11B, the surrounding through hole SRH according to the embodiment of the present specification may be formed from the periphery end of the bezel area BZA to the location at which the inclined end of the second encapsulation layer PCL starts.

Therefore, since the surrounding through hole SRH shown in FIG. 11B has a greater width than the surrounding through hole SRH shown in FIG. 11A, a larger amount of ultraviolet light may pass through the second encapsulation layer PCL to cure the second encapsulation layer PCL more quickly.

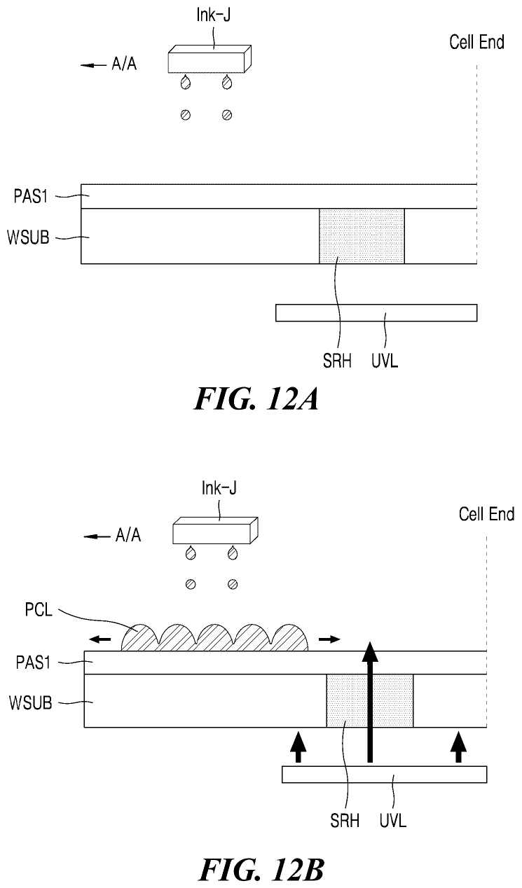

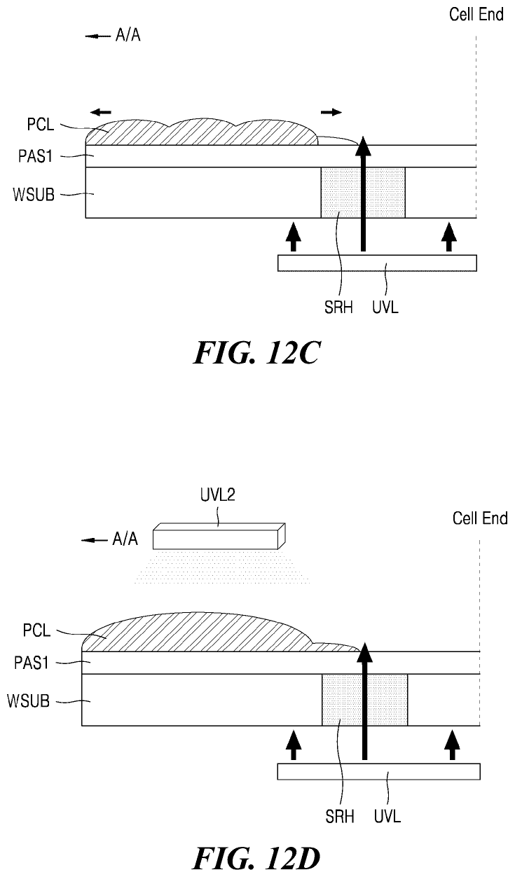

FIGS. 12A to 12D are views showing a process of curing the PCL by radiating light through the surrounding through hole according to the embodiment of the present specification.

Referring to FIG. 12A, the surrounding through hole SRH according to the embodiment of the present specification may be formed in the wafer substrate WSUB.

In this case, the first encapsulation layer PAS1 is disposed on the wafer substrate WSUB, and the resin component is supplied from the inkjet device Ink-J onto the first encapsulation layer PAS1.

Referring to FIG. 12B, the resin component supplied from the inkjet device Ink-J onto the first encapsulation layer PAS1 moves toward the cell end on the first encapsulation layer PAS1 to form the second encapsulation layer PCL.

In this case, the ultraviolet light supplied from the ultraviolet supply device UVL is radiated to pass through the first encapsulation layer PAS1 through the surrounding through hole SRH.

Referring to FIG. 12C, the second encapsulation layer PCL moving on the first encapsulation layer PAS1 is cured by the ultraviolet light radiated through the surrounding through hole SRH, and the end of the second encapsulation layer PCL is stopped at the location corresponding to the surrounding through hole SRH.

Referring to FIG. 12D, a second ultraviolet supply device UVL2 is located upward from the second encapsulation layer PCL, and the second ultraviolet supply device UVL2 radiates another ultraviolet light onto a surface of the second encapsulation layer PCL.

Therefore, the second encapsulation layer PCL is cured by ultraviolet light provided from the top and ultraviolet light radiated through the surrounding through hole SRH, and the end of the second encapsulation layer PCL is formed in the form of stopping at the location corresponding to the surrounding through hole SRH on the first encapsulation layer PAS1.

As described above, according to the embodiments of the present specification, it is possible to implement the display device in which reliability can be secured and the narrow bezel can be implemented by removing the structure of the dam, such as an engraved dam or an embossed dam, from the bezel area of the display device and preventing the occurrence of defects in the bezel area.

In addition, according to the embodiments of the present specification, it is possible to implement the display device in which the through hole in the form of surrounding the active area may be formed in the bezel area of the display panel, and when the particle cover layer PCL is formed in the manufacturing process, the particle cover layer PCL may be cured by radiating ultraviolet light through the through hole of the bezel area.

According to the embodiments of the present specification, the surrounding through hole SRH passing through the display panel in the form of surrounding the periphery of the active area may be disposed in the bezel area.

Therefore, since the particle cover layer PCL is cured by radiating the particle cover layer PCL with ultraviolet light through the surrounding through hole SRH when the particle cover layer PCL moves to the bezel area in the manufacturing process, the particle cover layer PCL may be formed in the bezel area by stopping the movement of the particle cover layer PCL.

Therefore, it is possible to improve the quality of the display device by preventing the occurrence of the traces of the seam visible from the bezel area of the display panel.

In addition, according to the embodiments of the present specification, by forming the particle cover layer PCL in the bezel area without the structure of the engraved dam or the embossed dam, it is possible to reduce the number of processes of forming the dam by removing the dam and reduce the manufacturing cost accordingly. Therefore, it is possible to reduce the manufacturing energy.

In addition, according to the embodiments of the present specification, it is possible to prevent the occurrence of defects in the bezel area of the display device, thereby preventing the reduction in the lifetime of the display panel.

In addition, according to the embodiments of the present specification, it is possible to prevent the occurrence of defects in the bezel area of the display device, thereby implementing the stable narrow bezel.

In addition, according to the embodiments of the present specification, it is possible to prevent the occurrence of defects in the bezel area of the display device, thereby minimizing the reduction in the lifetime of the panel and improving the quality of the display device.

It is possible to prevent the defects in the bezel area through the surrounding through hole without the structure of the dam in the bezel area of the display device according to the present specification, thereby easily implementing the narrow bezel.

The effects of the present specification are not limited to the above-described effects, and other effects that are not mentioned will be able to be clearly understood by those skilled in the art from the following description.

Specific effects of the present specification together with the above-described effects are described together with a description of the following detailed matters for carrying out the embodiments of the specification.

Although the present specification has been described above with reference to the exemplary drawings, the present specification is not limited by the embodiments and drawings disclosed in the present specification, and it is apparent that various modifications can be made by those skilled in the art within the scope of the technical spirit of the present specification. In addition, even when the operational effects according to the configuration of the present specification have not been explicitly described in the description of the embodiments of the present specification, it goes without saying that the effects predictable by the corresponding configuration should also be recognized.

### DESCRIPTION OF REFERENCE NUMERALS

10: display device
10′: display panel
12: data driver
13: gate driver
14: controller
15: host system
16: touch driving circuit
17: touch controller
30: first back plate
31: fixing member
32: adhesive member
33: second back plate
34: bending protection layer
80: cover window
81: optical film
82: adhesive
83: upper substrate
84: black ink
200: encapsulation layer
SRH: surrounding through hole
AA: active area
NA: non-active area
BZA: bezel area
BA: bending area
AE: anode electrode
PX: light emitting element (pixel)
D-IC: driving integrated circuit
WSUB: wafer substrate
SUB: substrate
TFTL: TR layer
PLN: planarization layer
PXL: pixel layer
ENCAP: encapsulation layer
TL: touch layer

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including an active area in which one or more pixels are disposed, and a bezel area disposed adjacent to the active area; and
a surrounding through hole disposed in the bezel area, the surrounding through hole surrounding a periphery of the active area and extending into the display panel.

2. The display device of claim 1, wherein the surrounding through hole is disposed between one or more anode electrodes disposed in the bezel area and one or more pixels disposed at the periphery of the active area.

3. The display device of claim 1, wherein a light emitting layer mask, a cathode electrode contact, a cathode electrode, and a cathode capping layer are disposed between the surrounding through hole and the active area.

4. The display device of claim 1, wherein a sawing margin, a wafer cell edge, and an insulation layer are disposed between the surrounding through hole and a periphery end of the bezel area.

5. The display device of claim 1, wherein the surrounding through hole has transparent ink, a glass material, or a transparent material.

6. The display device of claim 1, wherein the surrounding through hole is formed in a wafer substrate including the display panel.

7. The display device of claim 6, wherein one or more anode electrode patterns are disposed on the wafer substrate,
a first encapsulation layer is disposed on the wafer substrate and the one or more anode electrode patterns,
a second encapsulation layer is disposed on the first encapsulation layer, and
a third encapsulation layer is disposed on the second encapsulation layer.

8. The display device of claim 7, wherein an end of the second encapsulation layer is located at a location corresponding to the surrounding through hole.

9. The display device of claim 8, wherein the surrounding through hole is formed in the wafer substrate between an anode electrode pattern located at a periphery end of the bezel area and an anode electrode pattern next located therefrom.

10. The display device of claim 6, wherein a first insulating layer is disposed on the wafer substrate,
a signal line is disposed on the first insulating layer,
a first planarization layer is disposed on the signal line,
a second planarization layer is disposed on the first planarization layer,
a first encapsulation layer is disposed on the second planarization layer, and
a second encapsulation layer is disposed on the first encapsulation layer.

11. The display device of claim 10, wherein an end of the second encapsulation layer is located at a location corresponding to the surrounding through hole, and
the signal line is electrically connected to a connection electrode on the first planarization layer and a connection electrode on the second planarization layer via contact holes at the location corresponding to the surrounding through hole.

12. The display device of claim 6, wherein a first encapsulation layer is disposed on the wafer substrate,
a second encapsulation layer is disposed on the first encapsulation layer,
a third encapsulation layer is disposed on the second encapsulation layer, and
the surrounding through hole is spaced by a selected distance from a periphery end of the bezel area and formed in the wafer substrate, and an end of the second encapsulation layer is formed to be inclined at a location corresponding to the surrounding through hole.

13. The display device of claim 1, wherein the surrounding through hole passing through the display panel is formed on a black matrix,
a glass layer is disposed on the black matrix,
a first encapsulation layer is disposed on the glass layer,
a second encapsulation layer is disposed on the first encapsulation layer,
a third encapsulation layer is disposed on the second encapsulation layer, and
an end of the second encapsulation layer is located to be inclined at a location corresponding to the surrounding through hole.

14. The display device of claim 13, wherein the surrounding through hole is spaced by a selected distance from a periphery end of the bezel area and formed in the black matrix.

15. The display device of claim 13, wherein the surrounding through hole is formed from a periphery end of the bezel area to a location at which the inclined end of the second encapsulation layer starts.

16. A display device comprising:
a display panel having an active area and a bezel area adjacent to the active area, the display panel including:
one or more pixels disposed in the active area;
a wafer substrate; and
a surrounding through hole disposed in the bezel area,
wherein the surrounding through hole extends through the wafer substrate,
wherein the surrounding through hole surrounds the active area of the display panel when seen from a plan view.

17. The display device of claim 16, further comprising:
one or more anode electrodes disposed in the bezel area,
wherein the surrounding through hole is disposed between the one or more anode electrodes disposed in the bezel area and the one or more pixels disposed in the active area.

18. The display device of claim 16, wherein the surrounding through hole have therein a transparent material.

19. The display device of claim 16, further comprising:
a first encapsulation layer on the wafer substrate, the first encapsulation layer having a first surface and a second surface opposite the first surface; and
a second encapsulation layer on the second surface of the first encapsulation layer, the second encapsulation layer having an end portion, and
wherein the end portion of the second encapsulation layer overlaps with the surrounding through hole from a plan view.

20. The display device of claim 19, wherein the end portion of the second encapsulation layer has an inclination angle with respect to the second surface of the first encapsulation layer,
wherein the end portion of the second encapsulation layer fully overlaps with the surrounding through hole from a plan view.

21. The display device of claim 19, further comprising:
a third encapsulation layer on the second encapsulation layer, the third encapsulation layer having an end portion,
wherein the end portion of the third encapsulation layer is on and covers the end portion of the second encapsulation layer, and
wherein the end portion of the third encapsulation layer overlaps with the surrounding through hole from a plan view.

22. A display device comprising:
a display panel having an active area and a bezel area adjacent to the active area, the display panel including:
one or more pixels disposed in the active area;
a glass layer having a first surface and a second surface opposite the first surface;
a black matrix on the first surface of the glass layer; and
a surrounding through hole disposed in the bezel area,
wherein the surrounding through hole extends through the black matrix,
wherein the surrounding through hole surrounds the active area of the display panel when seen from a plan view.

23. The display device of claim 22, further comprising:
a first encapsulation layer on the second surface of the glass layer; and
a second encapsulation layer on the first encapsulation layer, the second encapsulation layer having an end portion, and
wherein the end portion of the second encapsulation layer overlaps with the surrounding through hole from a plan view.

24. The display device of claim 23, further comprising:
a third encapsulation layer on the second encapsulation layer, the third encapsulation layer having an end portion,
wherein the end portion of the third encapsulation layer is on and covers the end portion of the second encapsulation layer, and
wherein the end portion of the third encapsulation layer overlaps with the surrounding through hole from a plan view.
